(19) United States
(12) Patent Application Publication
(10) Pub. No.: US 2026/0299723 A1
(43) Pub. Date: Oct. 1, 2026

(54) TOUCH DISPLAY DEVICE, DISPLAY PANEL AND TOUCH DRIVING METHOD

(71) Applicant: LG Display Co., Ltd., Seoul (KR)

(72) Inventor: DeukSu LEE, Paju-si (KR)

(21) Appl. No.: 19/415,724

(22) Filed: Dec. 10, 2025

(30) Foreign Application Priority Data
Mar. 25, 2025 (KR) 10-2025-0037719

(51) Int. Cl. G06F 3/041; G06F 3/044; G06F 3/0354

(52) U.S. Cl. CPC G06F 3/04166; G06F 3/0412; G06F 3/04164; G06F 3/0445; G06F 3/0446; G06F 3/03545

(57) ABSTRACT

A touch display device includes a plurality of layers such as a substrate, a circuit layer disposed over the substrate and including a circuit for driving a plurality of subpixels, a pixel layer disposed over the circuit layer and including the plurality of subpixels, an encapsulation layer disposed to cover the pixel layer, a touch electrode layer disposed over the encapsulation layer and including a plurality of touch electrodes capable of sensing both finger touch and pen touch in an integrated manner, and a touch circuit that senses the finger touch in a first touch period and senses the pen touch in a second touch period through touch lines connected to the plurality of touch electrodes.

### CROSS REFERENCE TO RELATED APPLICATION

This application claims priority from and the benefit of Korean Patent Application No. 10-2025-0037719, filed on Mar. 25, 2025, which is hereby incorporated by reference for all purposes as if fully set forth herein.

### BACKGROUND

### Field

Embodiments of the invention relate generally to a touch display device, a display panel, and a touch driving method, and more particularly, to a touch display device, a display panel, and a touch driving method including a touch electrode layer capable of sensing both finger touch and pen touch in an integrated manner.

### Discussion of the Background

As information technology has advanced, the market for display devices serving as a medium for connection between a user and information has expanded. Accordingly, the use of various display devices, such as an organic light-emitting display (OLED), a quantum dot display (QDD), a liquid crystal display (LCD), and a plasma display panel (PDP), has increased. Among these display devices, the organic light-emitting display utilizes a self-emitting organic light-emitting diode and therefore has advantages such as fast response speed, high contrast ratio, high light emission efficiency, high luminance, and a wide viewing angle.

A display device may include a plurality of subpixels arranged in a display panel, each of which includes a light-emitting device, and may display an image by controlling luminance represented by each subpixel through voltage control applied to the light-emitting device to cause it to emit light.

In line with these developments, display devices have been further improved with various components configured to implement or enhance such display functions. For example, a display device may function as a touch display device that detects a user's finger touch or pen touch on the display panel and performs input processing based on the detected touch.

For finger touch, a sensing method utilizing capacitance is mainly employed, while for pen touch, an electromagnetic resonance (EMR) method is mainly employed.

In general, in order to sense both finger touch and pen touch together, a touch electrode for finger touch and a digitizer for EMR sensing for pen touch must be separately disposed, which increases the thickness of the touch display device and manufacturing costs.

The above information disclosed in this Background section is only for understanding of the background of the inventive concepts, and, therefore, it may contain information that does not constitute prior art.

### SUMMARY

Embodiments of the invention may provide a touch display device, a display panel, and a touch driving method including a touch electrode layer capable of sensing both finger touch and pen touch in an integrated manner.

Embodiments of the invention may provide a touch display device, a display panel, and a touch driving method having a structure of a touch electrode layer capable of effectively sensing a finger touch of a capacitance sensing structure and a pen touch of an EMR sensing structure.

Embodiments of the invention may provide a touch display device, a display panel, and a touch driving method capable of driving a touch electrode layer that can sense both finger touch and pen touch in an integrated manner so as to effectively distinguish between the finger touch and the pen touch.

Additional features of the inventive concepts will be set forth in the description which follows, and in part will be apparent from the description, or may be learned by practice of the inventive concepts.

A touch display device according to embodiments of the invention may include: a substrate; a circuit layer disposed over the substrate and including a circuit for driving a plurality of subpixels; a pixel layer disposed over the circuit layer and including the plurality of subpixels; an encapsulation layer disposed to cover the pixel layer; a touch electrode layer disposed over the encapsulation layer and including a plurality of touch electrodes for sensing both finger touch and pen touch; and a touch circuit that senses the finger touch in a first touch period and senses the pen touch in a second touch period through touch lines connected to the plurality of touch electrodes.

The touch electrode layer may include: a first touch electrode layer in which a first touch electrode is formed; an interlayer insulating film disposed on an upper portion of the first touch electrode layer; and a second touch electrode layer disposed on an upper portion of the interlayer insulating film, the second touch electrode layer having a second touch electrode formed therein.

The first touch electrode may extend in a first direction and may include a plurality of first touch electrode lines having one side connected to a first touch line and formed in an open structure and an opposite side formed in a closed structure in which the lines are connected to each other, and the second touch electrode may extend in a second direction different from the first direction and may include a plurality of second touch electrode lines having one side connected to a second touch line and formed in an open structure and an opposite side formed in a closed structure in which the lines are connected to each other, and a third touch electrode may be formed in either the first touch electrode layer or the second touch electrode layer and may be connected to a third touch line.

The third touch electrode may be formed in an island structure in a grid space in which the first touch electrode and the second touch electrode do not overlap.

A line width of the plurality of first touch electrode lines may be the same as a line width of the plurality of second touch electrode lines, and the third touch electrode may have a rectangular structure having one side equal to the line width of the first touch electrode lines or the line width of the second touch electrode lines.

A spacing distance and a line width between the plurality of first touch electrode lines may be the same as a spacing distance and a line width between the plurality of second touch electrode lines.

When the third touch electrode is formed in the same layer as the first touch electrode, the touch circuit may supply a touch driving signal to the first touch electrode and sense the finger touch using a touch sensing signal transmitted from the third touch electrode.

When the third touch electrode is formed in the same layer as the second touch electrode, the touch circuit may supply a touch driving signal to the second touch electrode and sense the finger touch using a touch sensing signal transmitted from the third touch electrode.

A size of the third touch electrode may decrease along a direction in which the third touch line extends.

The touch circuit may supply the touch driving signal to both the first touch electrode and the second touch electrode, and may sense the finger touch using the touch sensing signal transmitted from the third touch electrode.

The touch circuit may include a switching circuit connected to the first touch line and the second touch line, and may control the switching circuit to sequentially form a closed loop with respect to the plurality of first touch electrode lines while transmitting the touch driving signal and receiving the touch sensing signal, and to sequentially form a closed loop with respect to the plurality of second touch electrode lines while transmitting the touch driving signal and receiving the touch sensing signal.

A display panel according to embodiments of the invention may include: a substrate; a circuit layer disposed on the substrate and including a circuit for driving a plurality of subpixels; a pixel layer disposed over the circuit layer and including the plurality of subpixels; an encapsulation layer disposed to cover the pixel layer; and a touch electrode layer disposed over the encapsulation layer and including a plurality of touch electrodes for sensing both finger touch and pen touch.

The touch electrode layer may include: a first touch electrode layer in which a first touch electrode is formed; an interlayer insulating film disposed on an upper portion of the first touch electrode layer; and a second touch electrode layer disposed on an upper portion of the interlayer insulating film, the second touch electrode layer having a second touch electrode formed therein.

The first touch electrode may extend in a first direction and may include a plurality of first touch electrode lines having one side connected to a first touch line and formed in an open structure and an opposite side formed in a closed structure in which the lines are connected to each other, and the second touch electrode may extend in a second direction different from the first direction and may include a plurality of second touch electrode lines having one side connected to a second touch line and formed in an open structure and an opposite side formed in a closed structure in which the lines are connected to each other, and a third touch electrode may be formed in either the first touch electrode layer or the second touch electrode layer and may be connected to a third touch line.

A spacing distance and a line width between the plurality of first touch electrode lines may be the same as a spacing distance and a line width between the plurality of second touch electrode lines.

A touch driving method according to embodiments of the invention for driving a display panel including a touch electrode layer in which a first touch electrode, a second touch electrode, and a third touch electrode are formed may include: in a first touch period, supplying a touch driving signal to the first touch electrode or the second touch electrode, and sensing a finger touch using a touch sensing signal transmitted from the third touch electrode; and in a second touch period different from the first touch period, sensing a pen touch while controlling the first touch electrode and the second touch electrode to sequentially form a closed loop.

When the third touch electrode is formed in the same layer as the first touch electrode, the sensing of the finger touch may include supplying the touch driving signal to the first touch electrode and sensing the finger touch using the touch sensing signal transmitted from the third touch electrode.

When the third touch electrode is formed in the same layer as the second touch electrode, the sensing of the finger touch may include supplying the touch driving signal to the second touch electrode and sensing the finger touch using the touch sensing signal transmitted from the third touch electrode.

The sensing of the finger touch may include supplying the touch driving signal to both the first touch electrode and the second touch electrode, and sensing the finger touch using the touch sensing signal transmitted from the third touch electrode.

The first voltage level may have a value higher than the second voltage level.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a diagram structurally illustrating a touch display device according to an embodiment of the invention.

FIG. 2 is a diagram illustrating an example of a structure of a display panel according to an embodiment of the invention.

FIG. 3 is a cross-sectional view illustrating an example of a touch electrode layer in the touch display device according to an embodiment of the invention.

FIG. 4 is a plan view illustrating an example of a touch electrode layer in the touch display device according to an embodiment of the invention.

FIGS. 5 and FIG. 6 are plan views respectively illustrating examples of a first touch electrode layer and a second touch electrode layer configuring the touch electrode layer in the touch display device according to embodiments of the invention.

FIG. 7 is an enlarged plan view illustrating an arrangement of touch electrodes in the touch display device according to an embodiment of the invention.

FIG. 8 is a diagram illustrating an example of driving timing of the touch driving method according to an embodiment of the invention.

FIG. 9 is a conceptual diagram illustrating an operation of sensing a finger touch in the touch display device according to an embodiment of the invention.

FIG. 10 is another conceptual diagram illustrating an operation of sensing a finger touch in the touch display device according to an embodiment of the invention.

FIG. 11 is a conceptual diagram illustrating an operation of sensing a pen touch in the touch display device according to an embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

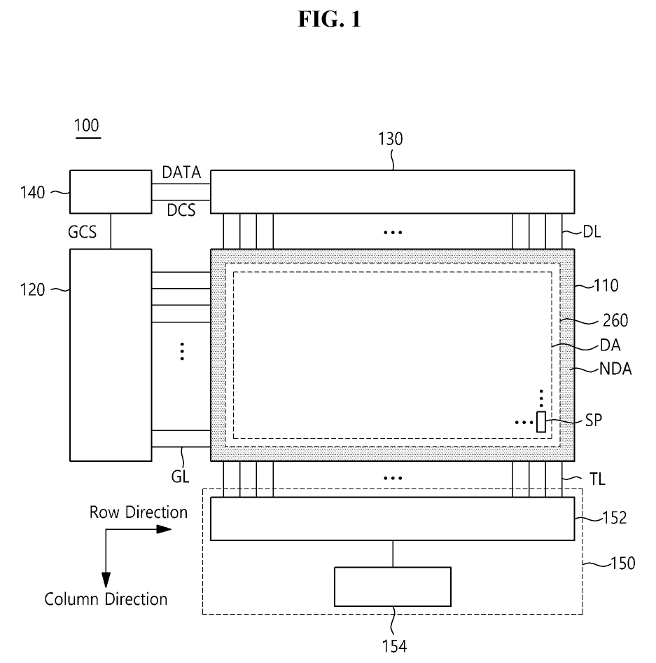

FIG. 1 is a diagram structurally illustrating a touch display device according to an embodiment of the invention.

Referring to FIG. 1, a touch display device 100 according to an embodiment of the invention may include, as components for image display, a display panel 110, a data driving circuit 130, a gate driving circuit 120, and a timing controller 140.

The display panel 110 may include a display area (DA) in which an image is displayed and a non-display area (NDA) in which an image is not displayed.

The non-display area (NDA) may be an outer peripheral area of the display area (DA), and may also be referred to as a bezel area. The non-display area (NDA) may be an area visible from the front surface of the display device 100, or may be a bent portion so as to be invisible from the front surface of the touch display device 100.

The display panel 110 may include a plurality of subpixels SP. For example, the touch display device 100 may be various types of display devices including a liquid crystal display device, an organic light-emitting display device, a micro light-emitting diode (micro LED) display device, or a quantum dot display device; however, embodiments of the invention are not limited thereto.

A structure of each of the plurality of subpixels SP may vary depending on a type of the touch display device 100. For example, when the touch display device 100 is a self-emitting display device in which each subpixel SP emits light by itself, each subpixel SP may include a light-emitting device that emits light by itself, one or more transistors, and one or more capacitors.

In addition, the display panel 110 may further include various types of signal lines for driving the plurality of subpixels SP. For example, the various types of signal lines may include a plurality of data lines DL for delivering a data signal (also referred to as a data voltage or image data) and a plurality of gate lines GL for delivering a gate signal (also referred to as a scan signal or light emission signal).

The plurality of data lines DL and the plurality of gate lines GL may intersect each other. Each of the plurality of data lines DL may be disposed so as to extend in a column direction. Each of the plurality of gate lines GL may be disposed so as to extend in a row direction.

The data driving circuit 130 may be a circuit for driving the plurality of data lines DL. The data driving circuit 130 may output the data signal to the plurality of data lines DL. The gate driving circuit 120 may be a circuit for driving the plurality of gate lines GL and may output the gate signal to the plurality of gate lines GL.

The timing controller 140 may control the data driving circuit 130 and the gate driving circuit 120. The timing controller 140 may control driving timing for the plurality of data lines DL and driving timing for the plurality of gate lines GL.

The timing controller 140 may supply various types of data driving control signals (DCS) to the data driving circuit 130 to control the data driving circuit 130, and may supply various types of gate driving control signals (GCS) to the gate driving circuit 120 to control the gate driving circuit 120.

The data driving circuit 130 may supply the data signal to the plurality of data lines DL according to the driving timing control of the timing controller 140. The data driving circuit 130 may receive digital image data DATA from the timing controller 140, convert the received image data DATA into the data signal in an analog form, and output the data signal to the plurality of data lines DL. In addition, the data driving circuit 130 may include one or more source driving integrated circuits (SDICs).

The gate driving circuit 120 may supply the gate signal to the plurality of gate lines GL according to timing control of the timing controller 140. The gate driving circuit 120 may receive a first gate voltage corresponding to a turn-on level voltage and a second gate voltage corresponding to a turn-off level voltage together with various types of gate driving control signals (GCS), generate the gate signal, and supply the generated gate signal to the plurality of gate lines GL.

The gate driving circuit 120 may be disposed outside the display panel 110 or may be disposed in the non-display area (NDA) or in the display area (DA) of the display panel 110. In addition, the gate driving circuit 120 may include one or more gate driving integrated circuits (GDICs).

The touch display device 100 may include, in addition to an image display function, a touch screen panel and a touch circuit 150 that senses the touch screen panel to detect whether a touch is generated by a touch object such as a finger or a pen, or to detect a touch position, in order to further provide a touch sensing function.

The touch circuit 150 may include a touch driving circuit 152 configured to drive and sense the touch screen panel to generate and output touch sensing data, and a touch controller 154 configured to detect touch occurrence or detect a touch position using the touch sensing data.

The touch screen panel may include a touch electrode layer 260 in which a plurality of touch electrodes are disposed. The touch screen panel may include a plurality of touch lines TL for electrically connecting the touch electrode layer 260 and the touch driving circuit 152. The touch screen panel or the touch electrode layer 260 may be a touch sensor.

The touch screen panel may be disposed outside the display panel 110 or inside the display panel 110. When the touch screen panel is outside the display panel 110, it may be referred to as an external touch screen panel. In the case of the external type, the touch screen panel and the display panel 110 may be separately manufactured and then combined. The external touch screen panel may include a substrate and the touch electrode layer 260 on the substrate.

When the touch screen panel is inside the display panel 110, it may be referred to as an internal touch screen panel. In the case of the internal type, the touch screen panel may be formed inside the display panel 110 during a manufacturing process of the display panel 110.

The touch driving circuit 152 may supply a touch driving signal to at least one touch electrode configuring the touch electrode layer 260, detect a touch sensing signal transmitted from at least one touch electrode configuring the touch electrode layer 260, and generate touch sensing data.

In the case of finger touch, the touch circuit 150 may perform touch sensing using a self-capacitance sensing method or a mutual-capacitance sensing method; however, embodiments of the invention are not limited thereto.

According to the mutual-capacitance sensing method, the touch electrode layer 260 may include a driving touch electrode and a sensing touch electrode. The touch driving circuit 152 may drive the driving touch electrode using the touch driving signal and detect the touch sensing signal from the sensing touch electrode.

According to the self-capacitance sensing method, the touch electrode layer 260 may serve as both a driving touch electrode and a sensing touch electrode. The touch driving circuit 152 may drive all or some of the touch electrodes constituting the touch electrode layer 260 and sense all or some of the touch electrodes.

In the case of EMR pen touch, a touch driving signal may be applied to at least some of the touch electrodes constituting the touch electrode layer 260, and a pen signal resonated by the touch driving signal may be sensed through the touch electrodes.

The touch driving circuit 152 and the touch controller 154 may be implemented as separate devices or as a single device.

The touch display device 100 according to embodiments of the invention may be a self-emitting display device in which a light-emitting device capable of self-emission is disposed in the display panel 110, such as an organic light-emitting display device, a quantum dot display device, or a micro light-emitting diode display device, without being limited thereto.

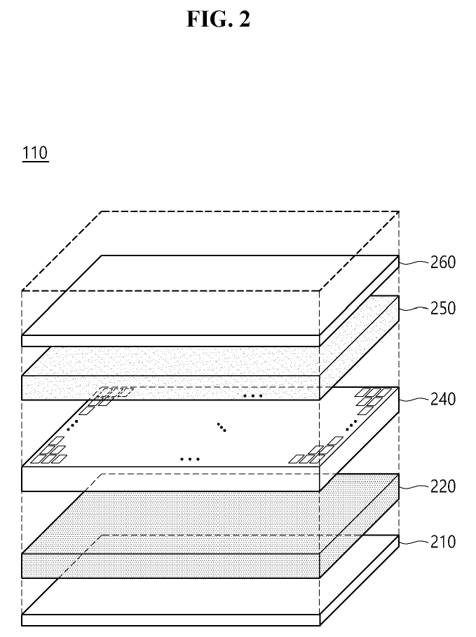

FIG. 2 is a diagram illustrating an example of a structure of a display panel according to an embodiment of the invention.

Referring to FIG. 2, the display panel 110 according to an embodiment of the invention may include a substrate 210, a circuit layer 220, a pixel layer 240, an encapsulation layer 250, and the touch electrode layer 260.

The pixel layer 240 may be a layer in which a plurality of subpixels SP are formed and may be disposed on the substrate 210. The pixel layer 240 may include the plurality of subpixels SP disposed in the display area (DA) in which an image is displayed.

The circuit layer 220 may be disposed between the substrate 210 and the pixel layer 240. The circuit layer 220 may be a layer in which a subpixel circuit for driving the subpixels SP is formed. When the gate driving circuit 120 is formed as a gate-in-array type, the gate driving circuit 120 may be included in the circuit layer 220 in other embodiments.

The encapsulation layer 250 may be disposed on the pixel layer 240. The encapsulation layer 250 may prevent an organic film disposed in the pixel layer 240 from being exposed to moisture or oxygen.

The touch electrode layer 260 in which the touch electrodes are formed may be disposed on the upper portion of the encapsulation layer 250. In some embodiments, a touch buffer layer may be additionally disposed between the encapsulation layer 250 and the touch electrode layer 260.

In the mutual-capacitance sensing method, the touch electrode layer 260 may include a driving touch electrode to which the touch driving signal is supplied and a sensing touch electrode for detecting the touch sensing signal.

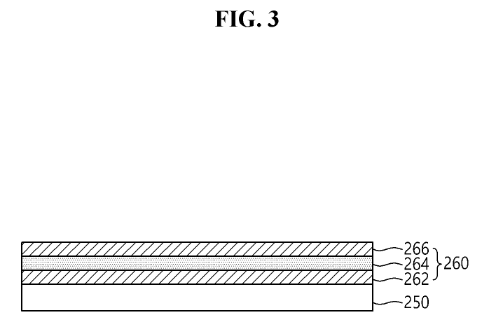

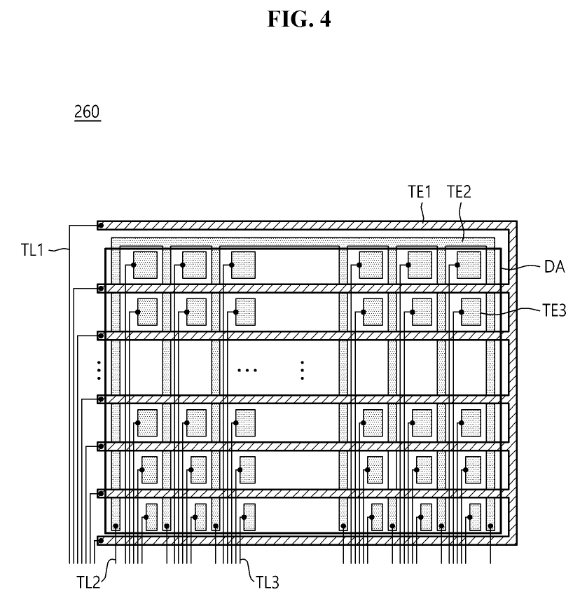

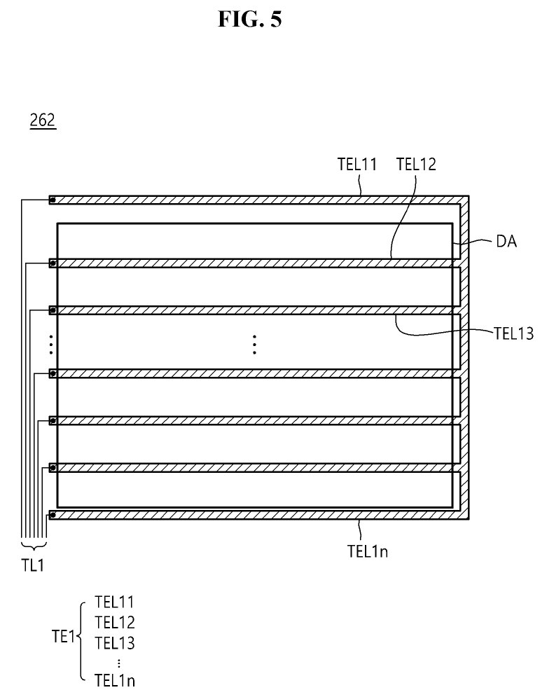

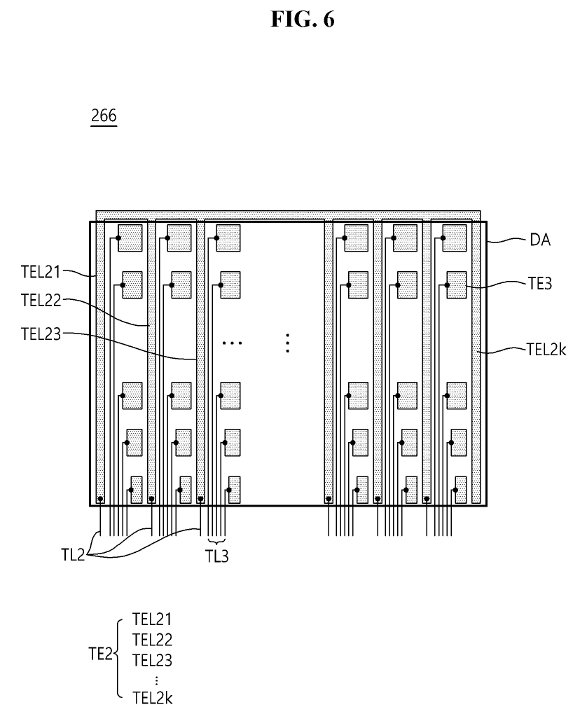

FIG. 3 is a cross-sectional view illustrating an example of the touch electrode layer in the touch display device according to an embodiment of the invention, FIG. 4 is a plan view illustrating an example of the touch electrode layer, and FIGS. 5 and FIG. 6 are plan views respectively illustrating a first touch electrode layer and a second touch electrode layer configuring the touch electrode layer according to an embodiment of the invention.

Referring to FIGS. 3 -FIG. 6 , in the touch display device 100 according to an embodiment of the invention, the touch electrode layer 260 may include a first touch electrode layer 262, an interlayer insulating film 264, and a second touch electrode layer 266 to integrally sense both finger touch and pen touch.

The first touch electrode layer 262 may be formed on an upper portion of the encapsulation layer 250, and may be formed of a triple-layer metal structure of Ti/Al/Ti, without being limited thereto.

The interlayer insulating film 264 may be formed of an insulating material such as silicon nitride (SiNx) to electrically insulate the first touch electrode layer 262 and the second touch electrode layer 266 from each other.

The second touch electrode layer 266 may be formed on an upper portion of the interlayer insulating film 264, and may be formed of a triple-layer metal structure of Ti/Al/Ti, without being limited thereto.

More particularly, the first touch electrode layer 262 and the second touch electrode layer 266 may be formed of the same material, thereby simplifying a manufacturing process. However, the inventive concepts are not limited thereto, and in some embodiments, the first touch electrode layer 262 and the second touch electrode layer 266 may be formed of different materials.

Referring to FIGS. 4 and FIG. 5, in the touch display device 100 according to embodiments of the invention, a first touch electrode TE1 extending in a first direction may be disposed in the first touch electrode layer 262.

The first direction is illustrated as a horizontal direction as an example, but a vertical direction may correspond to the first direction.

The first touch electrode TE1 may be formed of a plurality of first touch electrode lines TEL11 to TEL1n extending in the first direction. More particularly, the first touch electrode TE1 may include the plurality of first touch electrode lines TEL11 to TEL1n having a bar pattern.

The first touch electrode TE1 may be formed of n (n is a natural number of 2 or more) first touch electrode lines TEL11 to TEL1n extending in the first direction, and n first touch lines TL1 may be respectively connected thereto. In this case, one side of the first touch electrode lines TEL11 to TEL1n to which the first touch line TL1 is connected may be formed in an open structure, and the opposite side thereof may be formed in a closed structure in which the first touch electrode lines TEL11 to TEL1n are connected to each other.

In general, the first touch line TL1 may be connected to the first touch electrode lines TEL11 to TEL1n of the open structure, and the touch driving signal may be applied to the first touch electrode TE1 through the first touch line TL1.

The touch driving signal may be simultaneously applied to the n first touch lines TL1, or the touch driving signal may be sequentially applied in units of two or more of the plurality of first touch lines TL1.

Referring to FIGS. 4 and FIG. 6 , in the touch display device 100 according to embodiments of the invention, a second touch electrode TE2 extending in a second direction may be disposed in the second touch electrode layer 266.

The second direction is a direction different from the first direction and is illustrated as a vertical direction as an example.

The second touch electrode TE2 may be formed of a plurality of second touch electrode lines TEL21 to TEL2k extending in the second direction. More particularly, the second touch electrode TE2 may include the plurality of second touch electrode lines TEL21 to TEL2k having a bar pattern.

The second touch electrode TE2 may be formed of k (k is a natural number of 2 or more) second touch electrode lines TEL21 to TEL2k extending in the second direction, and k second touch lines TL2 may be respectively connected thereto. In this case, one side of the second touch electrode lines TEL21 to TEL2k to which the second touch line TL2 is connected may be formed in an open structure, and an opposite side thereof may be formed in a closed structure in which the second touch electrode lines TEL21 to TEL2k are connected to each other.

In general, the second touch line TL2 may be connected to the second touch electrode lines TEL21 to TEL2k of the open structure, and the touch driving signal may be applied to the second touch electrode TE2 through the second touch line TL2.

The touch driving signal may be simultaneously applied to the k second touch lines TL2, or the touch driving signal may be sequentially applied in units of two or more of the plurality of second touch lines TL2.

The first touch electrode TE1 and the second touch electrode TE2 may be used as touch electrodes for finger touch. In addition, the first touch electrode TE1 and the second touch electrode TE2 may be used as touch electrodes for pen touch.

More particularly, the first touch electrode TE1 or the second touch electrode TE2 may operate as a touch electrode for finger touch in the first touch period and may operate as a touch electrode for pen touch in the second touch period.

In addition, the touch display device 100 according to embodiments of the invention may include a third touch electrode TE3 corresponding to a sensing touch electrode for finger touch.

The third touch electrode TE3 may be formed in the first touch electrode layer 262 or in the second touch electrode layer 266. FIG. 6 exemplarily illustrates that the third touch electrode TE3 is formed in the second touch electrode layer 266, however, embodiments of the invention are not limited thereto.

The third touch electrode TE3 may be exposed from first touch electrode TE1 and the second touch electrode TE2 in a plan view. In particular, the third touch electrode TE3 may be disposed at a position not overlapping with the first touch electrode TE1 and the second touch electrode TE2.

For example, the third touch electrode TE3 may be formed separately in grid spaces in which the plurality of first touch electrode lines TEL11 to TEL1n and the plurality of second touch electrode lines TEL21 to TEL2k do not overlap. In particular, the third touch electrode TE3 may have an island-like polygonal structure. In one example, the third touch electrode TE3 may have a rectangular shape, without being limited thereto.

Each of the plurality of third touch electrodes TE3 may be connected to a third touch line TL3 extending in the first direction or the second direction. FIG. 6 exemplarily illustrates that the third touch line TL3 extends in the second direction, however, embodiments of the invention are not limited thereto.

The third touch electrode TE3 may transmit to the touch circuit through the third touch line TL3, a touch sensing signal generated by a touch driving signal applied to the first touch electrode TE1 or the second touch electrode TE2.

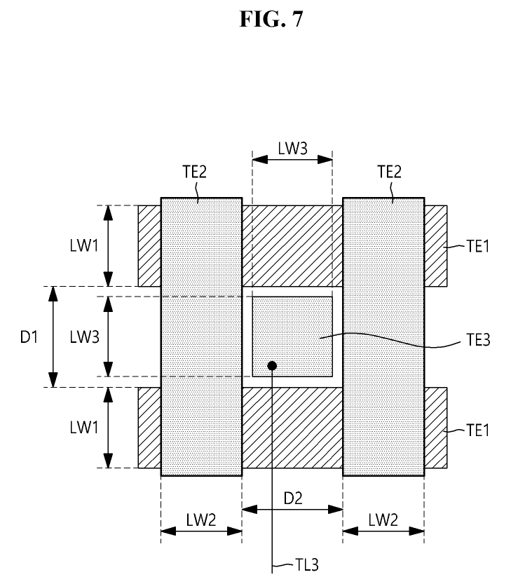

FIG. 7 is an enlarged plan view illustrating an arrangement of touch electrodes in the touch display device according to an embodiment of the invention.

Referring to FIG. 7, the touch display device 100 according to an embodiment of the invention may include the first touch electrode TE1, the second touch electrode TE2, and the third touch electrode TE3, which are capable of sensing both finger touch and pen touch together.

The first touch electrode TE1 may extend in the first direction and may include a plurality of first touch electrode lines having a bar pattern. The second touch electrode TE2 may extend in the second direction over the first touch electrode TE1 and may include a plurality of second touch electrode lines having a bar pattern. The third touch electrode TE3 may be disposed in a polygonal pattern at a position defined by the first touch electrode TE1 and the second touch electrode TE2. In an embodiment, the third touch electrode TE3 may not overlap the first touch electrode TE1 and the second touch electrode TE2.

In this case, in order to improve performance for finger touch using the capacitance sensing method, it is effective to increase an area in which the first touch electrode TE1 and the second touch electrode TE2, which operate as driving touch electrodes, face the third touch electrode TE3, which operates as a sensing touch electrode.

In general, the first touch electrodes TE1 extending in the first direction and the second touch electrodes TE2 extending in the second direction may be arranged in a grid form so that a spacing distance between the first touch electrodes TE1 and a spacing distance between the second touch electrodes TE2 are the same, and the third touch electrode TE3 may be disposed in an internal space between them.

For example, the first touch electrode TE1 may include first touch electrode lines in the form of bars having a first line width LW1 and disposed at intervals of a first spacing distance D1.

In addition, the second touch electrode TE2 may include second touch electrode lines in the form of bars having a second line width LW2 and disposed at intervals of a second spacing distance D2.

In this case, in an area where the first touch electrode TE1 and the second touch electrode TE2 do not overlap, a rectangular grid space having the first spacing distance D1 and the second spacing distance D2 may be formed. In general, the third touch electrode TE3 may be disposed within the grid space in a polygonal structure having a maximum line width equal to a third line width LW3. In one example, the first spacing distance D1 and the second spacing distance D2 may be the same, and the third touch electrode TE3 may have a square shape.

By arranging the first touch electrode TE1 and the second touch electrode TE2 in a grid form and disposing the third touch electrode TE3 having a rectangular structure in the grid space where the first touch electrode TE1 and the second touch electrode TE2 do not overlap, performance for finger touch using the capacitance sensing method can be improved.

In addition, when the first line width LW1 of the first touch electrode TE1 and the second line width LW2 of the second touch electrode TE2 are formed to be the same, a uniform resistance distribution can be formed, thereby reducing a resistance component of the pen touch operating in the EMR sensing method and improving sensing performance.

For example, the first line width LW1 of the first touch electrode TE1, the second line width LW2 of the second touch electrode TE2, and the third line width LW3 of the third touch electrode TE3 may all be formed to have the same size.

Alternatively, the first line width LW1 and the first spacing distance D1 of the first touch electrode TE1, and the second line width LW2 and the second spacing distance D2 of the second touch electrode TE2 may all be formed to have the same size. In this case, the third line width LW3 of the third touch electrode TE3 may be formed to be smaller than the first line width LW1 and the second line width LW2.

Meanwhile, in order to reduce influence by the third touch line TL3, a size of the third touch electrode TE3 may vary depending on a position. For example, when the third touch line TL3 extends in a downward direction, the size of the third touch electrode TE3 may decrease toward the downward direction.

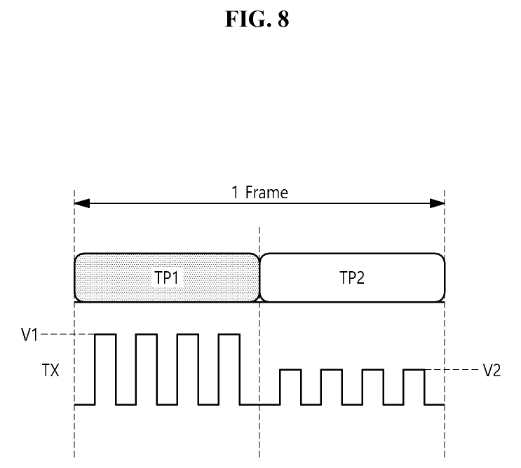

FIG. 8 is a diagram illustrating an example of driving timing of the touch driving method according to an embodiment of the invention.

Referring to FIG. 8, the touch driving method according to an embodiment of the invention may be performed such that a first touch period TP1 for sensing a finger touch and a second touch period TP2 for sensing a pen touch are performed in a time-division manner. The first touch period TP1 and the second touch period TP2 may be alternately performed within one frame.

During the first touch period TP1, a touch driving signal Tx having a first voltage level V1 may be applied through the first touch electrode TE1 or the second touch electrode TE2, and a touch sensing signal may be detected through the third touch electrode TE3.

During the second touch period TP2, a touch driving signal Tx having a second voltage level V2 may be sequentially applied through the first touch electrode TE1 and the second touch electrode TE2, and a touch sensing signal may be detected.

The first voltage level V1 is a high-level voltage for detecting finger touch by the capacitance sensing method, and the second voltage level V2 is a high-level voltage for detecting pen touch by the EMR method. The first voltage level V1 of the touch driving signal Tx for finger touch sensing by the capacitance sensing method may be higher than the second voltage level V2 of the touch driving signal Tx for pen touch sensing by the EMR method.

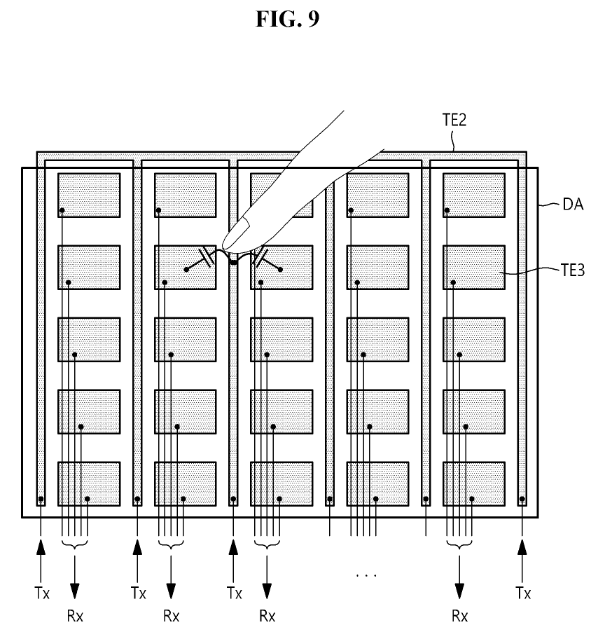

FIG. 9 is a conceptual diagram illustrating an operation of sensing a finger touch in the touch display device according to an embodiment of the invention.

Referring to FIG. 9, in order to sense a finger touch, the touch display device 100 according to an embodiment of the invention may use the second touch electrode TE2 as a driving touch electrode and the third touch electrode TE3 as a sensing touch electrode.

In this case, in the first touch period TP1, the touch driving signal Tx may be applied to the second touch electrode TE2, and the touch sensing signal Rx may be received through the third touch line TL3 connected to the third touch electrode TE3.

The touch driving circuit 152 may detect a touch position using the touch sensing signal Rx transmitted from the third touch electrode TE3.

The above description is based on a case in which the third touch electrode TE3 is disposed in the same layer as the second touch electrode TE2.

However, when the third touch electrode TE3 is disposed in the same layer as the first touch electrode TE1 in other embodiments, the first touch electrode TE1 may be used as the driving touch electrode and the third touch electrode TE3 may be used as the sensing touch electrode.

Meanwhile, in order to sense a finger touch, the touch display device 100 according to an embodiment of the invention may also use both the first touch electrode TE1 and the second touch electrode TE2 as driving touch electrodes and use the third touch electrode TE3 as a sensing touch electrode.

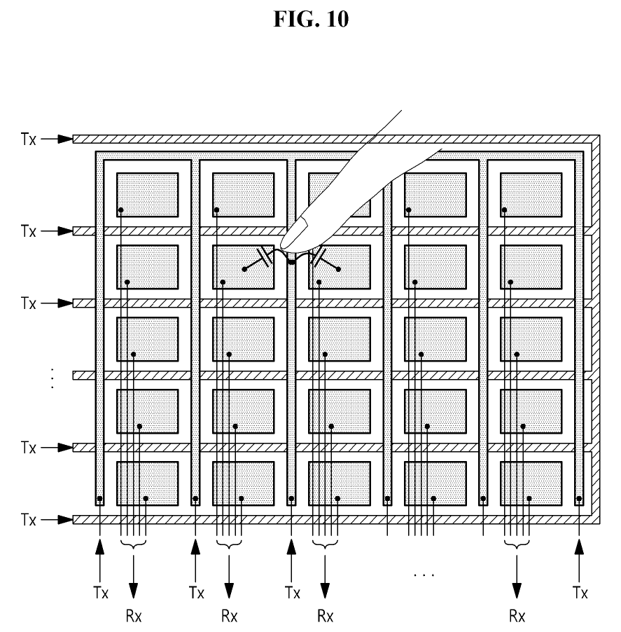

FIG. 10 is another conceptual diagram illustrating an operation of sensing a finger touch in the touch display device according to an embodiment of the invention.

Referring to FIG. 10, in order to sense a finger touch, the touch display device 100 according to an embodiment of the invention may use both the first touch electrode TE1 extending in the first direction and the second touch electrode TE2 extending in the second direction as driving touch electrodes.

The touch driving circuit 152 may apply the touch driving signal Tx to both the first touch electrode TE1 and the second touch electrode TE2 during the first touch period TP1.

In this case, capacitance of the third touch electrode TE3 may change depending on a position where a finger touch is present, and the touch sensing signal Rx may be transmitted to the touch driving circuit 152 through the third touch line TL3 connected to the third touch electrode TE3.

The touch driving circuit 152 may detect a position of the finger touch using the touch sensing signal Rx transmitted from the third touch electrode TE3.

Meanwhile, the touch display device 100 according to an embodiment the invention may sense a pen touch using the first touch electrode TE1 and the second touch electrode TE2.

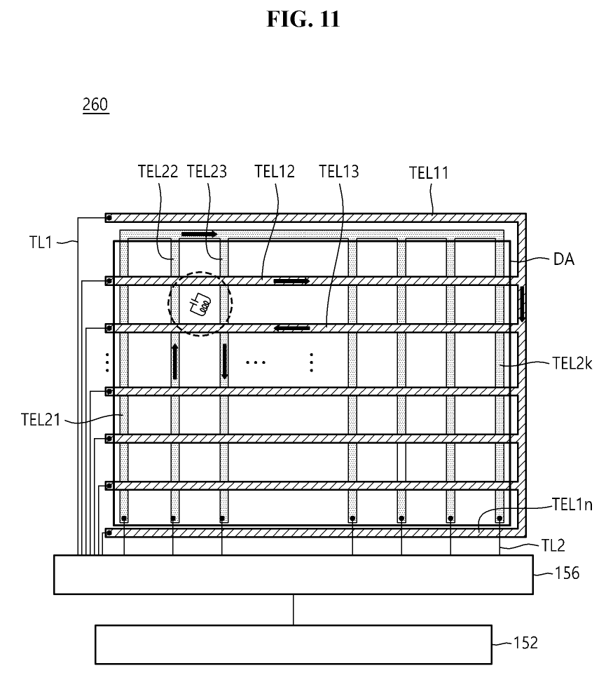

FIG. 11 is a conceptual diagram illustrating an operation of sensing a pen touch in the touch display device according to an embodiment of the invention.

Referring to FIG. 11, the touch display device 100 according to an embodiment of the invention may sense a finger touch in the first touch period TP1 and sense a pen touch in the second touch period TP2.

In order to sense pen touch by the EMR method in the second touch period TP2, the first touch electrode TE1 extending in the first direction and the second touch electrode TE2 extending in the second direction may be used.

First, for the n first touch electrode lines TEL11 to TEL1n configuring the first touch electrode TE1, the touch driving signal may be transmitted while sequentially forming a closed loop.

For example, among the n first touch electrode lines TEL11 to TEL1n, the first touch line TL1 may be connected so that the 1-1 touch electrode line TEL11 and the 1-2 touch electrode line TEL12 form a closed loop, and the touch driving signal may be supplied to the 1-1 touch electrode line TEL11. The touch driving circuit 152 may detect whether a pen is located in an area surrounded by the 1-1 touch electrode line TEL11 and the 1-2 touch electrode line TEL12 through the touch sensing signal transmitted via the 1-2 touch electrode line TEL12.

Then, the 1-2 touch electrode line TEL12 and the 1-3 touch electrode line TEL13 may be connected to form a closed loop, and the touch driving signal may be supplied to the 1-2 touch electrode line TEL12. The touch driving circuit 152 may detect whether a pen is located in an area surrounded by the 1-2 touch electrode line TEL12 and the 1-3 touch electrode line TEL13 through the touch sensing signal transmitted via the 1-3 touch electrode line TEL13.

In this manner, by sequentially forming closed loops for the n first touch electrode lines TEL11 to TEL1n and transmitting the touch driving signal, an area where the pen is located can be detected.

In addition, for the k second touch electrode lines TEL21 to TEL2k configuring the second touch electrode TE2, the touch driving signal may be transmitted while sequentially forming closed loops.

For example, among the k second touch electrode lines TEL21 to TEL2k, the second touch line TL2 may be connected so that the 2-1 touch electrode line TEL21 and the 2-2 touch electrode line TEL22 form a closed loop, and the touch driving signal may be supplied to the 2-1 touch electrode line TEL21. The touch driving circuit 152 may detect whether a pen is located in an area surrounded by the 2-1 touch electrode line TEL21 and the 2-1 touch electrode line TEL22 through the touch sensing signal transmitted via the 2-2 touch electrode line TEL22.

Then, the 2-2 touch electrode line TEL22 and the 2-3 touch electrode line TEL23 may be connected to form a closed loop, and the touch driving signal may be supplied to the 2-2 touch electrode line TEL22. The touch driving circuit 152 may detect whether a pen is located in an area surrounded by the 2-2 touch electrode line TEL22 and the 2-3 touch electrode line TEL23 through the touch sensing signal transmitted via the 2-3 touch electrode line TEL23.

In this manner, the touch display device 100 according to an embodiment of the invention may detect an area where the pen is located by sequentially forming closed loops for the n first touch electrode lines TEL11 to TEL1n and the k second touch electrode lines TEL21 to TEL2k and transmitting the touch driving signal.

Accordingly, the touch display device 100 according to an embodiment of the invention may include a switching circuit 156 capable of controlling connection of the first touch line TL1 or the second touch line TL2. The switching circuit 156 may be disposed inside the touch circuit 150 or outside the touch circuit 150.

As described above, the touch display device 100 according to an embodiment of the invention may sense pen touch by the EMR method using the first touch electrode TE1 and the second touch electrode TE2 and may sense finger touch using the third touch electrode TE3 disposed in an island structure in a grid space where the first touch electrode TE1 and the second touch electrode TE2 do not overlap.

In this case, the touch display device 100 according to an embodiment the invention may dispose the first touch electrode TE1 and the second touch electrode TE2 in the touch electrode layers separated by the interlayer insulating film, and dispose the third touch electrode TE3 in the same layer as the first touch electrode TE1 or the second touch electrode TE2, thereby enabling sensing of finger touch and pen touch while reducing a thickness of the display panel 110.

The touch display device according to embodiments of the invention may be described as follows.

According to embodiments of the invention, a touch display device, a display panel, and a touch driving method including a touch electrode layer capable of sensing both finger touch and pen touch in an integrated manner may be provided.

According to embodiments of the invention, a touch display device, a display panel, and a touch driving method having a structure of a touch electrode layer capable of effectively sensing a finger touch of a capacitance sensing structure and a pen touch of an EMR sensing structure may be provided.

According to embodiments of the invention, a touch display device, a display panel, and a touch driving method capable of driving a touch electrode layer that can sense both finger touch and pen touch in an integrated manner so as to effectively distinguish between the finger touch and the pen touch may be provided.

According to embodiments of the invention, manufacturing costs can be reduced through process optimization, and a lightweight touch display device and display panel may be provided.

Although certain embodiments and implementations have been described herein, other embodiments and modifications will be apparent from this description. Accordingly, the inventive concepts are not b such embodiments, but rather to the broader scope of the appended claims and various obvious modifications and equivalent arrangements as would be apparent to a person of ordinary skill in the art.

What is claimed is:

1. A touch display device comprising:
a substrate;
a circuit layer disposed over the substrate and including a circuit for driving a plurality of subpixels;
a pixel layer including the plurality of subpixels disposed over the circuit layer;
an encapsulation layer disposed to cover the pixel layer;
a touch electrode layer including a plurality of touch electrodes for sensing both finger touch and pen touch disposed over the encapsulation layer; and
a touch circuit configured to sense the finger touch in a first touch period and sense the pen touch in a second touch period through touch lines connected to the plurality of touch electrodes.

2. The touch display device of claim 1, wherein the touch electrode layer comprises:
a first touch electrode layer in which a first touch electrode is formed;
an interlayer insulating film disposed over the first touch electrode layer; and
a second touch electrode layer including a second touch electrode disposed over the interlayer insulating film.

3. The touch display device of claim 2, wherein the first touch electrode comprises a plurality of first touch electrode lines extending in a first direction, one of the first touch electrode lines having one side connected to a first touch line and formed in an open structure, and an opposite side formed in a closed structure to be connected to other first touch electrode lines,
wherein the second touch electrode comprises a plurality of second touch electrode lines extending in a second direction different from the first direction, one of the second touch electrode lines having one side connected to a second touch line and formed in an open structure, and an opposite side formed in a closed structure to be connected to other second touch electrode lines, and
wherein a third touch electrode is formed in either the first touch electrode layer or the second touch electrode layer and is connected to a third touch line.

4. The touch display device of claim 3, wherein the third touch electrode has an island structure and is disposed in a grid space defined by the first touch electrode and the second touch electrode.

5. The touch display device of claim 3, wherein a line width of the plurality of first touch electrode lines is the same as a line width of the plurality of second touch electrode lines, and
wherein the third touch electrode has a rectangular structure having one side equal to the line width of the first touch electrode lines or the line width of the second touch electrode lines.

6. The touch display device of claim 3, wherein a spacing distance and a line width between the plurality of first touch electrode lines are the same as a spacing distance and a line width between the plurality of second touch electrode lines, respectively.

7. The touch display device of claim 3, wherein, when the third touch electrode is formed in the same layer as the first touch electrode, the touch circuit is configured to supply a touch driving signal to the first touch electrode and sense the finger touch using a touch sensing signal transmitted from the third touch electrode.

8. The touch display device of claim 3, wherein, when the third touch electrode is formed in the same layer as the second touch electrode, the touch circuit is configured to supply a touch driving signal to the second touch electrode and sense the finger touch using a touch sensing signal transmitted from the third touch electrode.

9. The touch display device of claim 3, wherein the third touch electrode has a size that decreases along a direction in which the third touch line extends.

10. The touch display device of claim 3, wherein the touch circuit is configured to supply a touch driving signal to both the first touch electrode and the second touch electrode and sense the finger touch using a touch sensing signal transmitted from the third touch electrode.

11. The touch display device of claim 3, wherein the touch circuit includes a switching circuit connected to the first touch line and the second touch line, and
wherein the switching circuit is configured to form a closed loop sequentially with respect to the plurality of first touch electrode lines while transmitting a touch driving signal and receiving a touch sensing signal, and to form a closed loop sequentially with respect to the plurality of second touch electrode lines while transmitting the touch driving signal and receiving the touch sensing signal.

12. A display panel comprising:
a substrate;
a circuit layer disposed on the substrate and including a circuit for driving a plurality of subpixels;
a pixel layer including the plurality of subpixels disposed over the circuit layer;
an encapsulation layer disposed to cover the pixel layer; and
a touch electrode layer including a plurality of touch electrodes for sensing both finger touch and pen touch disposed over the encapsulation layer.

13. The display panel of claim 12, wherein the touch electrode layer includes:
a first touch electrode layer in which a first touch electrode is formed;
an interlayer insulating film disposed over the first touch electrode layer; and
a second touch electrode layer including a second touch electrode disposed over the interlayer insulating film.

14. The display panel of claim 13, wherein the first touch electrode comprises a plurality of first touch electrode lines extending in a first direction, one of the first touch electrode lines having one side connected to a first touch line and formed in an open structure, and an opposite side formed in a closed structure to be connected to other first touch electrode lines,
wherein the second touch electrode comprises a plurality of second touch electrode lines extending in a second direction different from the first direction, one of the second touch electrode lines having one side connected to a second touch line and formed in an open structure, and an opposite side formed in a closed structure to be connected to other second touch electrode lines, and
wherein a third touch electrode is formed in either the first touch electrode layer or the second touch electrode layer and is connected to a third touch line.

15. The display panel of claim 14, wherein the third touch electrode has an island structure and is disposed in a grid space defined by the first touch electrode and the second touch electrode.

16. A touch driving method for driving a display panel including a touch electrode layer in which a first touch electrode, a second touch electrode, and a third touch electrode are formed, the method comprising:
in a first touch period, supplying a first touch driving signal having a first voltage level to the first touch electrode or the second touch electrode, and sensing a finger touch using a touch sensing signal transmitted from the third touch electrode; and
in a second touch period different from the first touch period, controlling the first touch electrode and the second touch electrode to sequentially form a closed loop, supplying a second touch driving signal having a second voltage level, and sensing a pen touch.

17. The touch driving method of claim 16, wherein, when the third touch electrode is formed in the same layer as the first touch electrode, the sensing of the finger touch comprises supplying the first touch driving signal to the first touch electrode and sensing the finger touch using the touch sensing signal transmitted from the third touch electrode.

18. The touch driving method of claim 16, wherein, when the third touch electrode is formed in the same layer as the second touch electrode, the sensing of the finger touch comprises supplying the first touch driving signal to the second touch electrode and sensing the finger touch using the touch sensing signal transmitted from the third touch electrode.

19. The touch driving method of claim 16, wherein the sensing of the finger touch comprises supplying the first touch driving signal to both the first touch electrode and the second touch electrode and sensing the finger touch using the touch sensing signal transmitted from the third touch electrode.

20. The touch driving method of claim 16, wherein the first voltage level is higher than the second voltage level.
